(19) United States
(12) Patent Application Publication
(10) Pub. No.: US 2010/0102417 A1
(43) Pub. Date: Apr. 29, 2010

(54) VAPOR DEPOSITION METHOD FOR TERNARY COMPOUNDS

(75) Inventors: Seshadri Ganguli, Sunnyvale, CA (US); Srinivas Gandikota, Santa Clara, CA (US); Sang Ho Yu, Cupertino, CA (US); Luis Felipe Hakim, Fremont, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/606,444

(22) Filed: Oct. 27, 2009

Related U.S. Application Data
(60) Provisional application No. 61/108,755, filed on Oct. 27, 2008.

(51) Int. Cl. H01L 29/00; C23C 16/34; C23C 16/44

(52) U.S. Cl. 257/532; 427/535; 257/E29.001

(57) ABSTRACT

Embodiments provide a method for depositing or forming titanium aluminum nitride materials during a vapor deposition process, such as atomic layer deposition (ALD) or plasma-enhanced ALD (PE-ALD). In some embodiments, a titanium aluminum nitride material is formed by sequentially exposing a substrate to a titanium precursor and a nitrogen plasma to form a titanium nitride layer, exposing the titanium nitride layer to a plasma treatment process, and exposing the titanium nitride layer to an aluminum precursor while depositing an aluminum layer thereon. The process may be repeated multiple times to deposit a plurality of titanium nitride and aluminum layers. Subsequently, the substrate may be annealed to form the titanium aluminum nitride material from the plurality of layers. In other embodiments, the titanium aluminum nitride material may be formed by sequentially exposing the substrate to the nitrogen plasma and a deposition gas which contains the titanium and aluminum precursors.

### CROSS-REFERENCE TO RELATED APPLICATION

This application claims benefit of U.S. Ser. No. 61/108,755, filed Oct. 27, 2008, which is hereby incorporated by reference in its entirety.

### BACKGROUND OF THE INVENTION

1. Field of the Invention

Embodiments of the invention generally relate to methods for depositing materials, and more particularly to vapor deposition processes for forming materials containing ternary compounds.

2. Description of the Related Art

In the field of semiconductor processing, flat-panel display processing, or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

While conventional chemical vapor deposition (CVD) has proved successful for device geometries and aspect ratios down to 0.15 μm, the more aggressive device geometries require an alternative deposition technique. One technique that is receiving considerable attention is atomic layer deposition (ALD). During a traditional ALD process, reactant gases are sequentially introduced into a processing chamber containing a substrate.

Thermally induced ALD processes are the most common ALD technique and use heat to cause the chemical reaction between the two reactants. While thermal ALD processes work well to deposit some materials, the processes often have a slow deposition rate. Therefore, fabrication throughput may be impacted to an unacceptable level. The deposition rate may be increased at a higher deposition temperature, but many chemical precursors, especially metal-organic compounds, decompose at elevated temperatures.

The formation of materials by plasma-enhanced ALD (PE-ALD) processes is also a known technique. In some examples of traditional PE-ALD processes, a material may be formed from the same chemical precursors as a thermal ALD process, but with a higher deposition rate and at a lower temperature. Although several variations of techniques exist, in general, a PE-ALD process provides that a reactant gas and a reactant plasma are sequentially introduced into a processing chamber containing a substrate.

While PE-ALD processes overcome some of the shortcomings of thermal ALD processes due to the high degree of reactivity of the reactant radicals within the plasma, PE-ALD processes have many limitations. For example, PE-ALD process may cause plasma damage to a substrate (e.g., etching), be incompatible with certain chemical precursors, and require additional hardware.

Therefore, there is a need for a process for depositing or forming a material on a substrate by a vapor deposition technique, preferably by a plasma-enhanced technique, such as by a PE-ALD technique.

### SUMMARY OF THE INVENTION

Embodiments of the invention provide a method for depositing or forming titanium nitride and titanium aluminum nitride materials on a substrate during a vapor deposition process, such as atomic layer deposition (ALD), plasma-enhanced ALD (PE-ALD), chemical vapor deposition (CVD), or plasma-enhanced CVD (PE-CVD). A processing chamber is configured to expose the substrate to a sequence of gases and/or plasmas during the vapor deposition process. In one embodiment, a method for forming a titanium material on the substrate surface is provided which includes sequentially exposing the substrate to a titanium precursor gas and a nitrogen precursor (e.g., plasma or gas) while forming a titanium nitride layer thereon, exposing the titanium nitride layer to a plasma during a treatment process, exposing the titanium nitride layer to an aluminum precursor gas while depositing an aluminum layer thereon, and heating the substrate to form a titanium aluminum nitride material from the titanium nitride layer and the aluminum layer.

In another embodiment, a method for forming a titanium material on the substrate surface is provided which includes sequentially exposing the substrate to the titanium precursor gas and the nitrogen precursor (e.g., plasma or gas) while forming a first titanium nitride layer thereon, exposing the first titanium nitride layer to a plasma during a treatment process, and exposing the first titanium nitride layer to the aluminum precursor gas while depositing a first aluminum layer thereon. The method further includes exposing the substrate sequentially to the titanium precursor gas and the nitrogen precursor while forming a second titanium nitride layer on the first aluminum layer, exposing the second titanium nitride layer to the plasma during the treatment process, and exposing the second titanium nitride layer to the aluminum precursor gas while depositing a second aluminum layer thereon. The cycle of depositing titanium nitride layers, treating, and depositing aluminum layers may be repeated numerous times to form a plurality of layers. Subsequently, the substrate may be heated or otherwise annealed to form a titanium aluminum nitride material from the layers. In some embodiments, the cycle of depositing and treating the titanium nitride layers and depositing aluminum layers thereon may also include treating each aluminum layer (e.g., inert gas plasma or nitrogen plasma) before depositing the next titanium nitride layer.

In another embodiment, a method for forming a titanium material on the substrate surface is provided which includes forming a titanium nitride layer on the substrate during a PE-ALD process, exposing the titanium nitride layer to a plasma during a treatment process, and exposing the titanium nitride layer to the aluminum precursor gas while depositing an aluminum layer thereon during a vapor deposition process. The method further includes sequentially repeating the PE-ALD process, the treatment process, and the vapor deposition process to form the titanium aluminum nitride material from a plurality of titanium nitride layers and aluminum layers. In other examples, the method further includes exposing the aluminum layer to an inert gas plasma or a nitrogen plasma during a plasma treatment process, and then sequentially repeating the PE-ALD process, the treatment process, the vapor deposition process, and the plasma treatment process to form the titanium aluminum nitride material from a plurality of titanium nitride layers and aluminum layers.

In other embodiments, a method for forming a titanium aluminum nitride material includes exposing the substrate to a deposition gas containing the titanium precursor and the aluminum precursor while forming an absorbed layer thereon, exposing the absorbed layer to a nitrogen plasma while forming a titanium aluminum nitride layer on the substrate, and repeating sequential exposures of the deposition gas and the nitrogen plasma to form a plurality of titanium aluminum nitride layers on the substrate.

In some embodiments, the titanium precursor gas may contain the titanium precursor such as tetrakis(dimethylamino) titanium (TDMAT), tetrakis(diethylamino) titanium (TDEAT), tetrakis(methylethylamino) titanium (TEMAT), titanium tetrachloride, or derivatives thereof. In some embodiments, the aluminum precursor gas contains the aluminum precursor which includes tris(tertbutyl) aluminum (TTBA), trimethyl aluminum (TMA), aluminum chloride, and derivatives thereof. In one example, the titanium precursor is TDMAT and the aluminum precursor is TTBA. In some embodiments, a nitrogen plasma may be used during a deposition process or during a treatment process. The nitrogen plasma may be formed from a gas containing nitrogen, ammonia, hydrogen, argon, derivatives thereof, or mixtures thereof. The nitrogen plasma may be formed or ignited outside the processing chamber by a remote plasma system (RPS) or inside the processing chamber an in situ plasma system. In one example, a titanium material may be formed or otherwise deposited on the substrate surface during a PE-ALD process which includes TDMAT as the titanium precursor, TTBA as the aluminum precursor, and a nitrogen plasma as the nitrogen precursor. The titanium aluminum nitride material may contain an aluminum concentration within a range from about 2 atomic percent to about 40 atomic percent, preferably, from about 5 atomic percent to about 33 atomic percent.

In another embodiment, the titanium aluminum nitride material may be a metal gate layer on the substrate. The metal gate layer containing titanium aluminum nitride may have a thickness within a range from about 10 Å to about 100 Å, preferably, from about 20 Å to about 80 Å, and more preferably, from about 30 Å to about 40 Å. In another embodiment, the titanium aluminum nitride material may be a barrier layer on the substrate. The barrier layer containing the titanium aluminum nitride material may have a thickness within a range from about 5 Å to about 50 Å, preferably, from about 15 Å to about 30 Å, for example, about 20 Å. In one embodiment, a metal-containing layer, such as a seed layer or a bulk layer, is disposed on or over the barrier layer containing the titanium aluminum nitride material. The metal-containing layer may contain copper, cobalt, ruthenium, tungsten, palladium, aluminum, alloys thereof, or combinations thereof. In another embodiment, the titanium aluminum nitride material may be a layer within a capacitor. The capacitor layer of titanium aluminum nitride may have a thickness within a range from about 50 Å to about 500 Å, preferably, from about 100 Å to about 200 Å, for example, about 150 Å.

In another example, a titanium nitride layer may be formed by sequentially exposing the substrate to a remote nitrogen plasma and TDMAT during a PE-ALD process. In another example, a titanium aluminum nitride material may be formed by sequentially exposing the substrate to a remote nitrogen plasma, TDMAT, and TTBA during a PE-ALD process. The methods may be utilized to achieve good resistivity, homogenous treatment on side wall of high aspect ratio vias and trenches.

Processes described herein which utilize TDMAT as the titanium precursor usually form titanium nitride materials and titanium aluminum nitride materials which have no chlorine impurity or substantially no chlorine impurity, such as possible trace amounts. Also, processes described herein which utilize TDMAT and/or TTBA as precursors usually form titanium aluminum nitride materials which have no carbon impurity, a small carbon concentration (about 5 atomic percent or less), or a larger carbon concentration (greater than 5 atomic percent)—dependant on application of the titanium aluminum nitride material. In some embodiments, the titanium aluminum nitride material may contain a carbon concentration of about 5 atomic percent or less, preferably, about 3 atomic percent or less, and more preferably, about 2 atomic percent or less, and more preferably, about 1 atomic percent or less, and more preferably, about 0.5 atomic percent or less. In other embodiments, the titanium aluminum nitride material may contain a carbon concentration of about 15 atomic percent or less, such as about 10 atomic percent or less, such as about 5 atomic percent.

In some examples, the substrate or heater may be heated to a temperature within a range from about 340° C. to about 370° C. depending on aspect ratio of feature. During a plasma process, the chamber pressure may be within a range from about 500 mTorr to about 2 Torr, and the plasma power may be within a range from about 4 kW to about 10 kW. The nitrogen gas may have a flow rate within a range from about 200 sccm to about 2,000 sccm.

In another embodiment, the titanium aluminum nitride material described herein may be used to form a dynamic random access memory (DRAM) capacitor. In some examples, the DRAM capacitor may be a buried word line (bWL) DRAM or a buried bit line (bBL) DRAM. The DRAM capacitor may contain a bottom electrode containing the titanium aluminum nitride material and disposed over a contact surface, a high-k oxide layer disposed over the bottom electrode, and a top electrode containing the titanium aluminum nitride material and disposed over the high-k oxide layer. The contact surface contains a metal or other conductive material, such as titanium, tungsten, copper, cobalt, ruthenium, nickel, platinum, aluminum, silver, polysilicon, doped polysilicon, derivatives thereof, alloys thereof, and combinations thereof. The high-k oxide layer contains a high-k material which includes hafnium oxide, hafnium silicate, hafnium aluminum silicate, zirconium oxide, strontium titanium oxide, barium strontium titanate, derivatives thereof, silicates thereof, aluminates thereof, or combinations thereof. The bottom electrode, the high-k oxide layer, and the top electrode are deposited within a trench which is formed within an oxide material disposed on the substrate. Also, the bottom electrode or the top electrode containing the titanium aluminum nitride material may each independently have a thickness within a range from about 25 Å to about 500 Å, preferably, from about 50 Å to about 200 Å or from about 100 Å to about 200 Å.

### DETAILED DESCRIPTION

Embodiments of the invention provide a method for depositing or forming titanium nitride and titanium aluminum nitride materials on a substrate during a vapor deposition process, such as atomic layer deposition (ALD), plasma-enhanced ALD (PE-ALD), chemical vapor deposition (CVD), or plasma-enhanced CVD (PE-CVD). A processing chamber is configured to expose the substrate to a sequence of gases and/or plasmas during the vapor deposition process. In one aspect, the process has little or no initiation delay and maintains a fast deposition rate while forming the titanium material, which includes titanium aluminum nitride, titanium nitride, titanium silicon nitride, metallic titanium, derivatives thereof, or combinations thereof. In some embodiments described herein, the ALD or PE-ALD processes include sequentially exposing a substrate to various deposition gases or plasmas containing chemical precursors or reagents, such as a titanium precursor, an aluminum precursor, a nitrogen gas precursor and/or a nitrogen plasma, inert gas plasmas, other reagents, or combinations thereof.

In one embodiment, a titanium aluminum nitride material may be formed on the substrate surface by sequentially exposing the substrate to a titanium precursor gas and a nitrogen precursor (e.g., plasma or gas) to form a titanium nitride layer on the substrate, exposing the titanium nitride layer to a plasma during a treatment process, and exposing the titanium nitride layer to an aluminum precursor gas while depositing an aluminum layer on the titanium nitride layer. Subsequently, the substrate may be heated to form the titanium aluminum nitride material from the titanium nitride layer and the aluminum layer.

In another embodiment, the titanium aluminum nitride material may be formed on the substrate surface by sequentially exposing the substrate to the titanium precursor gas and a nitrogen plasma or a nitrogen precursor gas to form a titanium nitride layer on the substrate, exposing the titanium nitride layer to a first plasma (e.g., nitrogen plasma) during a first treatment process, exposing the titanium nitride layer to the aluminum precursor gas while depositing an aluminum layer on the titanium nitride layer, and exposing the aluminum layer to a second plasma (e.g., nitrogen plasma) during a second treatment process. Subsequently, the substrate may be heated to form the titanium aluminum nitride material from the titanium nitride layer and the aluminum layer. The first and second plasmas may independently be an inert plasma or a nitrogen plasma. In some examples, the nitrogen plasma may be formed from a gas containing ammonia or nitrogen.

In other embodiments, a method for forming a titanium material on the substrate surface is provided which includes sequentially exposing the substrate to the titanium precursor gas and the nitrogen precursor (e.g., plasma or gas) while forming a first titanium nitride layer thereon, exposing the first titanium nitride layer to a plasma during a treatment process, and exposing the first titanium nitride layer to the aluminum precursor gas while depositing a first aluminum layer thereon. The method further includes exposing the substrate sequentially to the titanium precursor gas and the nitrogen precursor while forming a second titanium nitride layer on the first aluminum layer, exposing the second titanium nitride layer to the plasma during the treatment process, and exposing the second titanium nitride layer to the aluminum precursor gas while depositing a second aluminum layer thereon. The cycle of depositing titanium nitride layers, treating, and depositing aluminum layers may be repeated numerous times to form a plurality of layers. Subsequently, the substrate may be heated or otherwise annealed to form a titanium aluminum nitride material from the layers. In some embodiments, the cycle of depositing and treating the titanium nitride layers and depositing aluminum layers thereon may also include treating each aluminum layer (e.g., inert gas plasma or nitrogen plasma) before depositing the next titanium nitride layer.

In another embodiment, a method for forming a titanium material on the substrate surface is provided which includes forming a titanium nitride layer on the substrate during a PE-ALD process, exposing the titanium nitride layer to a plasma during a treatment process, and exposing the titanium nitride layer to the aluminum precursor gas while depositing an aluminum layer thereon during a vapor deposition process. The method further includes sequentially repeating the PE-ALD process, the treatment process, and the vapor deposition process to form the titanium aluminum nitride material from a plurality of titanium nitride layers and aluminum layers. In other examples, the method further includes exposing the aluminum layer to an inert gas plasma or a nitrogen plasma during a plasma treatment process, and then sequentially repeating the PE-ALD process, the treatment process, the vapor deposition process, and the plasma treatment process to form the titanium aluminum nitride material from a plurality of titanium nitride layers and aluminum layers.

In other embodiments, a method for forming the titanium aluminum nitride material includes exposing the substrate to a deposition gas containing the titanium precursor and the aluminum precursor while forming an absorbed layer thereon, exposing the absorbed layer to a nitrogen plasma while forming a titanium aluminum nitride layer on the substrate, and repeating sequential exposures of the deposition gas and the nitrogen plasma to form a plurality of titanium aluminum nitride layers on the substrate.

In another embodiment, a method for forming the titanium aluminum nitride material includes forming a titanium aluminum layer on the substrate from a deposition gas containing the titanium precursor and the aluminum precursor during a vapor deposition process, and exposing the titanium aluminum layer to a nitrogen plasma during a nitridation process. The method further includes sequentially repeating the deposition cycles to form a plurality of the titanium aluminum nitride layers. An optional treatment process may be incorporated into the deposition cycle by exposing the titanium aluminum layer and/or the titanium aluminum nitride to a plasma, such as an inert gas plasma.

In some embodiments, the titanium precursor gas may contain the titanium precursor such as tetrakis(dimethylamino) titanium (TDMAT), tetrakis(diethylamino) titanium (TDEAT), tetrakis(methylethylamino) titanium (TEMAT), titanium tetrachloride, or derivatives thereof. In some embodiments, the aluminum precursor gas contains the aluminum precursor which includes tris(tertbutyl) aluminum (TTBA), trimethyl aluminum (TMA), aluminum chloride, and derivatives thereof. In one example, the titanium precursor is TDMAT and the aluminum precursor is TTBA. In some embodiments, a nitrogen plasma may be used during a deposition process or during a treatment process. The nitrogen plasma may be formed from a gas containing nitrogen, ammonia, hydrogen, argon, derivatives thereof, or mixtures thereof. The nitrogen plasma may be formed or ignited outside the processing chamber by a remote plasma system (RPS) or inside the processing chamber an in situ plasma system. In one example, a titanium material may be formed or otherwise deposited on the substrate surface during a PE-ALD process which includes TDMAT as the titanium precursor, TTBA as the aluminum precursor, and a nitrogen plasma as the nitrogen precursor. The titanium aluminum nitride material may contain an aluminum concentration within a range from about 2 atomic percent to about 40 atomic percent, preferably, from about 5 atomic percent to about 33 atomic percent.

In another embodiment, the titanium aluminum nitride material may be a metal gate layer on the substrate. The metal gate layer containing the titanium aluminum nitride material may have a thickness within a range from about 10 Å to about 100 Å, preferably, from about 20 Å to about 80 Å, and more preferably, from about 30 Å to about 40 Å.

In another embodiment, the titanium aluminum nitride material may be a barrier layer on the substrate. The barrier layer containing the titanium aluminum nitride material may have a thickness within a range from about 5 Å to about 50 Å, preferably, from about 15 Å to about 30 Å, for example, about 20 Å. In one embodiment, a metal-containing layer, such as a seed layer or a bulk layer, is disposed on or over the barrier layer containing the titanium aluminum nitride material. The metal-containing layer may contain copper, cobalt, ruthenium, tungsten, palladium, aluminum, alloys thereof, or combinations thereof. In another embodiment, the titanium aluminum nitride material may be a layer within a capacitor. The capacitor layer of titanium aluminum nitride may have a thickness within a range from about 50 Å to about 500 Å, preferably, from about 100 Å to about 200 Å, for example, about 150 Å.

In another example, a titanium nitride layer may be formed by sequentially exposing the substrate to a remote nitrogen plasma and TDMAT during a PE-ALD process. In another example, a titanium aluminum nitride material may be formed by sequentially exposing the substrate to a remote nitrogen plasma, TDMAT, and TTBA during a PE-ALD process. The methods may be utilized to achieve good resistivity, homogenous treatment on side wall of high aspect ratio vias and trenches. Processes described herein which utilize TDMAT as a titanium precursor usually form titanium nitride materials and titanium aluminum nitride materials which have no chlorine impurity or substantially no chlorine impurity, such as possible trace amounts. Also, processes described herein which utilize TDMAT and/or TTBA as precursors usually form titanium aluminum nitride materials which have no carbon impurity, a small carbon concentration (about 5 atomic percent or less), or a larger carbon concentration (greater than 5 atomic percent). In some embodiments, the titanium aluminum nitride material may contain a carbon concentration of about 5 atomic percent or less, preferably, about 3 atomic percent or less, and more preferably, about 2 atomic percent or less, and more preferably, about 1 atomic percent or less, and more preferably, about 0.5 atomic percent or less. In other embodiments, the titanium aluminum nitride material may contain a carbon concentration of about 15 atomic percent or less, such as about 10 atomic percent or less, such as about 5 atomic percent.

In another embodiment, the titanium aluminum nitride materials described herein may be used to form a dynamic random access memory (DRAM) capacitor. The DRAM capacitor may contain a bottom electrode containing titanium aluminum nitride and disposed over a contact surface, a high-k oxide layer disposed over the bottom electrode, and a top electrode containing titanium aluminum nitride and disposed over the high-k oxide layer. The contact surface may contain polysilicon, doped polysilicon, or derivatives thereof. Alternatively, the contact surface may contain a metal, such as tungsten, copper, aluminum, silver, cobalt, ruthenium, alloys thereof, or derivatives thereof. The high-k oxide layer contains a high-k material, such as zirconium oxide, strontium titanium oxide, barium strontium titanate, or derivatives thereof. The bottom electrode, the high-k oxide layer, and the top electrode are deposited within a trench which is formed within an oxide material disposed on the substrate. In various examples, the bottom electrode containing the titanium aluminum nitride material and/or the top electrode containing the titanium aluminum nitride material may each independently have a thickness within a range from about 25 Å to about 500 Å, preferably, from about 50 Å to about 200 Å or from about 100 Å to about 200 Å.

In many embodiments, the titanium precursors that may be used during the vapor deposition processes for depositing or forming titanium materials (e.g., titanium nitride or titanium aluminum nitride materials) described herein include tetrakis(dimethylamino) titanium (TDMAT), tetrakis(diethylamino) titanium (TDEAT), titanium tetrachloride (TiCl₄), or derivatives thereof. The nitrogen precursors that may be used to deposit or form titanium materials during the vapor deposition processes described herein include nitrogen (e.g., plasma, N₂, or atomic-N), ammonia (NH₃), hydrazine (N₂H₄), methylhydrazine (Me(H)NNH₂), dimethyl hydrazine (Me₂NNH₂ or Me(H)NN(H)Me), tertiarybutylhydrazine (^{t}Bu(H)NNH₂), phenylhydrazine (C₆H₅(H)NNH₂), a nitrogen plasma source (e.g., N, N₂, N₂/H₂, NH₃, or a N₂H₄ plasma), 2,2′-azotertbutane (^{t}BuNN^{t}Bu), an azide source, such as ethyl azide (EtN₃), trimethylsilyl azide (Me₃SiN₃), derivatives thereof, plasmas thereof, or combinations thereof.

In some embodiments, the titanium materials deposited or formed herein may contain aluminum, such as titanium aluminum nitride materials. The aluminum precursors that may be used with the vapor deposition processes described herein include aluminum compounds having the chemical formula of RₘAlX₍₃₋ₘ₎, where m is 0, 1, 2, or 3, each R is independently hydrogen, methyl, ethyl, propyl, butyl, amyl, methoxy, ethoxy, propoxy, butoxy, pentoxy, isomers thereof, and X is independently chlorine, bromine, fluorine, or iodine. Examples of aluminum precursors include tri(tertbutyl) aluminum (((CH₃)₃C)₃Al or ^{t}Bu₃Al or TTBA), tri(isopropyl) aluminum (((CH₃)₂C(H))₃Al or ⁱPr₃Al), triethylaluminum ((CH₃CH₂)₃Al or Et₃Al or TEA), trimethylaluminum ((CH₃)₃Al or Me₃Al or TMA), di(tertbutyl) aluminum hydride (((CH₃)₃C)₂AlH or ^{t}Bu₂AlH), di(isopropyl) aluminum hydride (((CH₃)₂C(H))₂AlH or ⁱPr₂AlH), diethylaluminum hydride ((CH₃CH₂)₂AlH or Et₂AlH), dimethylaluminum hydride ((CH₃)₂AlH or Me₂AlH), di(tertbutyl) aluminum chloride (((CH₃)₃C)₂AlCl or ^{t}Bu₂AlCl), di(isopropyl) aluminum chloride (((CH₃)₂C(H))₂AlCl or ⁱPr₂AlCl), diethylaluminum chloride ((CH₃CH₂)₂AlCl or Et₂AlCl), dimethylaluminum chloride ((CH₃)₂AlCl or Me₂AlCl), aluminum tertbutoxide (((CH₃)₃CO)₃Al or ^{t}BuO₃Al), aluminum isopropoxide (((CH₃)₂C(H)O)₃Al or ⁱPrO₃Al), aluminum triethoxide ((CH₃CH₂O)₃Al or EtO₃Al), aluminum trimethoxide ((CH₃O)₃Al or MeO₃Al), or derivatives thereof. The aluminum precursors may be used to form titanium aluminum nitride materials, aluminum nitride materials, as well as other aluminum-containing layers and materials by the deposition processes described herein.

A carrier gas, a purge gas, a deposition gas, or other process gas may contain nitrogen, hydrogen, ammonia, argon, neon, helium, or combinations thereof. Plasmas may be useful for depositing, forming, annealing, treating, or other processing of titanium materials described herein. The various plasmas described herein, such as the nitrogen plasma or the inert gas plasma, may be ignited from and/or contain a plasma precursor gas. The plasma precursor gas may contain nitrogen, hydrogen, ammonia, argon, neon, helium, or combinations thereof. In some examples, the nitrogen plasma contains nitrogen and hydrogen. In other examples, the nitrogen plasma contains nitrogen and ammonia. In another example, the nitrogen plasma contains ammonia and hydrogen. In other examples, the nitrogen plasma contains nitrogen, ammonia, and hydrogen. In other examples, the nitrogen plasma contains either nitrogen or ammonia.

In one embodiment, a titanium nitride material may be formed on a substrate. A deposition gas containing TDMAT may be pulsed into an inlet of a PE-ALD chamber, through a gas channel, from injection holes, and into a central channel and nitrogen plasma is sequentially pulsed from a RPS into the central channel from the inlet. Both the deposition gas containing TDMAT and the nitrogen plasma are sequentially pulsed to and through a showerhead. Thereafter, the substrate is sequentially exposed to the deposition gas and the nitrogen plasma to form a titanium nitride layer on the substrate. In some examples, the titanium nitride layer may have a thickness within a range from about 1 Å to about 20 Å, preferably, from about 2 Å to about 10 Å, and more preferably, from about 3 Å to about 7 Å, for example, about 5 Å. In other examples, a titanium nitride material, a plurality of titanium nitride layers, or a layer titanium nitride may have a thickness within a range from about 2 Å to about 300 Å, preferably, from about 5 Å to about 200 Å, for example, from about 2 Å to about 20 Å or from about 2 Å to about 50 Å.

The titanium nitride layer may be exposed to a treatment process, such as a plasma process or a thermal anneal. In one example, the titanium nitride layer is exposed to a nitrogen plasma (e.g., RPS of N₂ or NH₃). Thereafter, the titanium nitride layer is exposed to an aluminum precursor gas to form an aluminum layer thereon. The aluminum precursor gas contains an aluminum precursor and may contain a carrier gas, such as nitrogen, argon, hydrogen, helium, or mixtures thereof. In one example, the aluminum precursor gas contains TTBA and a carrier gas (e.g., Ar). In one example, the aluminum layer may be exposed to a nitrogen plasma or an inert gas plasma during a plasma treatment process. Subsequently, the substrate containing the titanium nitride and aluminum layers may be exposed to a thermal process, another plasma process, or an additional and/or alternative treatment process to form a titanium aluminum nitride material/layer.

A deposition gas containing TDMAT may be pulsed into the inlet of the PE-ALD chamber, through the gas channel, from injection holes, and into the central channel and nitrogen plasma is sequentially pulsed from a RPS into the central channel from the inlet. Both the deposition gas containing TDMAT and the nitrogen plasma may be sequentially pulsed to and through the showerhead. Thereafter, the substrate is sequentially exposed to the deposition gas and the nitrogen plasma to form a titanium nitride layer on the substrate.

In one example, a titanium aluminum nitride material may be formed on a substrate. A deposition gas containing TDMAT may be pulsed into an inlet, through a gas channel, from various holes or outlets, and into a central channel. An aluminum precursor gas containing TTBA may be pulsed into the inlets, through gas the channel, from the holes and outlets, and into the central channel. Alternatively, the aluminum precursor gas may be pulsed into another gas inlet, gas channel, and sets of holes (not shown) in order to be delivered into the central channel. In another embodiment, the aluminum precursor gas may be pulsed into the central channel from the inlet. Nitrogen plasma is sequentially pulsed from a RPS into the central channel from the inlet. The deposition gas containing TDMAT, the aluminum precursor gas containing TTBA, and the nitrogen plasma may be sequentially pulsed to and through a showerhead. Thereafter, the substrate is sequentially exposed to the deposition gas, the aluminum precursor, and the nitrogen plasma to form a titanium aluminum nitride layer on the substrate. The process for forming the titanium aluminum nitride layer may be repeated to form a titanium aluminum nitride material which contains a plurality of titanium nitride layers. In some embodiment, the substrate may be heated to a temperature within a range from about 500° C., preferably, about 400° C. or less, such as within a range from about 200° C. to about 400° C., and more preferably, from about 340° C. to about 370° C., for example, about 360° C. to form the titanium aluminum nitride layer. In another example, the aluminum layer may be exposed to a nitrogen plasma (e.g., N₂-RPS) to form the titanium aluminum nitride layer or after the titanium aluminum nitride layer.

In one embodiment, a titanium material (e.g., titanium nitride) may be formed during a PE-ALD process containing a constant flow of a reagent gas while providing sequential pulses of a titanium precursor and a plasma. In another embodiment, a titanium material may be formed during another PE-ALD process that provides sequential pulses of a titanium precursor (e.g., TDMAT) and a reagent plasma (e.g., nitrogen plasma). In both of these embodiments, the reagent is generally ionized during the process. The PE-ALD process provides that the plasma is generated external from the processing chamber, such as by a remote plasma generator (RPS) system. During PE-ALD processes, a plasma may be generated from a microwave (MW) frequency generator or a radio frequency (RF) generator. In another embodiment, a titanium material may be formed during a thermal ALD process that provides sequential pulses of a titanium precursor and a reagent.

In another embodiment, a titanium aluminum nitride or derivatives thereof may be formed during a PE-ALD process containing a constant flow of a reagent gas while providing sequential pulses of a titanium precursor, an aluminum precursor, and a plasma. In another embodiment, the titanium aluminum nitride material may be formed during another PE-ALD process that provides sequential pulses of a titanium precursor (e.g., TDMAT), an aluminum precursor (e.g., TTBA), and a reagent plasma (e.g., nitrogen plasma). In both of these embodiments, the reagent is generally ionized during the process. The PE-ALD process provides that the plasma is generated external from the processing chamber, such as by a remote plasma generator (RPS) system. During PE-ALD processes, a plasma may be generated from a microwave (MW) frequency generator or a radio frequency (RF) generator. In another embodiment, a titanium material may be formed during a thermal ALD process that provides sequential pulses of a titanium precursor, an aluminum precursor, and a reagent.

In alternatives embodiment, a titanium aluminum nitride material may be formed on a substrate by exposing the substrate simultaneously to a titanium precursor and an aluminum precursor. In one embodiment, the method includes exposing the substrate to a deposition gas containing a titanium precursor and an aluminum precursor while forming an absorbed layer thereon, exposing the absorbed layer to a nitrogen plasma while forming a titanium aluminum nitride layer on the substrate, and repeating sequential exposures of the deposition gas and the nitrogen plasma to form a plurality of titanium aluminum nitride layers on the substrate. In some embodiments, the titanium aluminum nitride layer may be exposed to a gas or plasma during a treatment process. In some examples, each titanium aluminum nitride layer may be exposed to a nitrogen plasma (e.g., N₂, NH₃, H₂, or mixtures thereof) during the treatment process. In other examples, each titanium aluminum nitride layer may be exposed to an inert gas plasma (e.g., Ar) during the treatment process.

In some examples, the titanium precursor (e.g., TDMAT) and the aluminum precursor (e.g., TTBA) may be co-flowed in a single deposition gas, and in other examples, the titanium and aluminum precursors may be independently and simultaneously flowed into the chamber. The deposition gas containing the titanium and aluminum precursors may be pulsed into the inlet of the PE-ALD chamber, through the gas channel, from injection holes, and into the central channel. In some examples, the nitrogen plasma is sequentially pulsed from a RPS into the central channel from the inlet. The deposition gas containing the titanium and aluminum precursors and the nitrogen plasma may be sequentially pulsed to and through the showerhead. Thereafter, the substrate may be sequentially exposed to the deposition gas and the nitrogen plasma to form the titanium aluminum nitride layer on the substrate.

In other examples, a nitrogen precursor gas is sequentially pulsed into the central channel from the inlet. The deposition gas containing the titanium and aluminum precursors and the nitrogen precursor gas may be sequentially pulsed to and through the showerhead. Thereafter, the nitrogen precursor gas may be ignited to form a nitrogen plasma, and the substrate may be sequentially exposed to the deposition gas and the nitrogen plasma to form a plurality of titanium aluminum nitride layers on the substrate.

In some embodiments, the titanium material may be formed during a PE-ALD process containing a constant flow of a reagent gas while providing sequential pulses of a titanium precursor and a plasma. In another embodiment, the titanium material may be formed during another PE-ALD process that provides sequential pulses of the titanium precursor and a reagent plasma. In another embodiment, the titanium material may be formed by sequentially exposing the substrate to a deposition gas and a nitrogen plasma during another PE-ALD process, where the deposition gas contains a titanium precursor and an aluminum precursor.

The plasma may be a nitrogen plasma or an inert gas plasma generated remotely or internally to the processing chamber. Also, the PE-ALD process provides that the plasma may be generated external from the processing chamber, such as by a remote plasma generator (RPS) system, or by a plasma generated within the processing chamber, such as an in situ PE-ALD chamber. In many examples, each of the titanium nitride layers, aluminum layers, titanium aluminum nitride materials/layers may be exposed to a nitrogen plasma (e.g., N₂, NH₃, H₂, or mixtures thereof) during a nitridation process or the plasma treatment process. In many examples, the nitrogen plasma may be formed by an RPS system, exposed to any of the layers, and may be formed from ammonia.

During PE-ALD processes, a plasma may be generated from a microwave (MW) frequency generator or a radio frequency (RF) generator. For example, a plasma may be ignited within a processing chamber or from a lid assembly. In one example, a nitrogen plasma is generated by an RPS, administered or injected into the processing or deposition chamber, and exposed to the substrate. In another example, the nitrogen plasma is generated in situ by a RF generator. In another embodiment, the titanium material or titanium nitride may be formed during a thermal ALD process that provides sequential pulses of a metal precursor and a reagent. During PE-ALD processes, for example, the plasma generator may be set to have a power output within a range from about 1 kilowatts (kW) to about 40 kW, preferably, from about 2 kW to about 20 kW, and more preferably, from about 4 kW to about 10 kW.

In many examples, the substrate or heater may be heated to a temperature within a range from about 340° C. to about 370° C. while depositing or forming titanium materials. During a plasma process for treating or depositing, the chamber pressure may be within a range from about 500 mTorr to about 2 Torr, and the plasma power may be within a range from about 4 kW to about 10 kW. The nitrogen gas may have a flow rate within a range from about 200 sccm to about 2,000 sccm.

In some embodiments, a plasma system and a processing chambers or systems which may be used during methods described here for depositing or forming titanium materials include the TXZ® CVD, chamber available from Applied Materials, Inc., located in Santa Clara, Calif. Further disclosure of plasma systems and processing chambers is described in commonly assigned U.S. Pat. Nos. 5,846,332, 6,079,356, and 6,106,625, which are incorporated herein by reference in their entirety, to provide further disclosure for a plasma generator, a plasma chamber, an ALD chamber, a substrate pedestal, and chamber liners. In other embodiments, a PE-ALD processing chamber or system which may be used during methods described here for depositing or forming titanium materials is described in commonly assigned U.S. Ser. No. 12/494,901, filed on Jun. 30, 2009, which is incorporated herein by reference in its entirety. An ALD processing chamber used during some embodiments described herein may contain a variety of lid assemblies. Other ALD processing chambers may also be used during some of the embodiments described herein and are available from Applied Materials, Inc., located in Santa Clara, Calif. A detailed description of an ALD processing chamber may be found in commonly assigned U.S. Pat. Nos. 6,878,206 and 6,916,398, and commonly assigned U.S. Ser. No. 10/281,079, filed on Oct. 25, 2002, and published as U.S. Pub. No. 2003-0121608, which are hereby incorporated by reference in their entirety. In another embodiment, a chamber configured to operate in both an ALD mode as well as a conventional CVD mode may be used to deposit titanium materials is described in commonly assigned U.S. Ser. No. 10/712,690, filed on Nov. 13, 2003, and published as U.S. Pub. No. 2004-0144311, which are each incorporated herein by reference in their entirety.

The ALD process provides that the processing chamber or the deposition chamber may be pressurized at a pressure within a range from about 0.01 Torr to about 80 Torr, preferably from about 0.1 Torr to about 10 Torr, and more preferably, from about 0.5 Torr to about 2 Torr. Also, the chamber or the substrate may be heated to a temperature of less than about 500° C., preferably, about 400° C. or less, such as within a range from about 200° C. to about 400° C., and more preferably, from about 340° C. to about 370° C., for example, about 360° C.

The substrate may be for example, a silicon substrate having an interconnect pattern defined in one or more dielectric material layers formed thereon. In one example, the substrate contains an adhesion layer thereon, while in another example, the substrate contains a dielectric surface. The processing chamber conditions such as, the temperature and pressure, are adjusted to enhance the adsorption of the deposition gases on the substrate so as to facilitate the reaction of the titanium precursor and the reagent gas.

In one embodiment, the substrate may be exposed to a reagent gas throughout the whole ALD cycle. The substrate may be exposed to a titanium precursor gas formed by passing a carrier gas (e.g., nitrogen or argon) through an ampoule of a titanium precursor. The ampoule may be heated depending on the titanium precursor used during the process. In one example, an ampoule containing TDMAT may be heated to a temperature within a range from about 25° C. to about 80° C. The titanium precursor gas usually has a flow rate within a range from about 100 sccm to about 2,000 sccm, preferably, from about 200 sccm to about 1,000 sccm, and more preferably, from about 300 sccm to about 700 sccm, for example, about 500 sccm. The titanium precursor gas and the reagent gas may be combined to form a deposition gas. A reagent gas usually has a flow rate within a range from about 100 sccm to about 3,000 sccm, preferably, from about 200 sccm to about 2,000 sccm, and more preferably, from about 500 sccm to about 1,500 sccm. In one example, nitrogen plasma is used as a reagent gas with a flow rate of about 1,500 sccm. The substrate may be exposed to the titanium precursor gas or the deposition gas containing the titanium precursor and the reagent gas for a time period within a range from about 0.1 seconds to about 8 seconds, preferably, from about 1 second to about 5 seconds, and more preferably, from about 2 seconds to about 4 seconds. The flow of the titanium precursor gas may be stopped once the titanium precursor is adsorbed on the substrate. The titanium precursor may be a discontinuous layer, continuous layer or even multiple layers.

The substrate and chamber may be exposed to a purge step after stopping the flow of the titanium precursor gas. The flow rate of the reagent gas may be maintained or adjusted from the previous step during the purge step. Preferably, the flow of the reagent gas is maintained from the previous step. Optionally, a purge gas may be administered into the processing chamber with a flow rate within a range from about 100 sccm to about 2,000 sccm, preferably, from about 200 sccm to about 1,000 sccm, and more preferably, from about 300 sccm to about 700 sccm, for example, about 500 sccm. The purge step removes any excess titanium precursor and other contaminants within the processing chamber. The purge step may be conducted for a time period within a range from about 0.1 seconds to about 8 seconds, preferably, from about 1 second to about 5 seconds, and more preferably, from about 2 seconds to about 4 seconds. The carrier gas, the purge gas, the deposition gas, or other process gas may contain nitrogen, hydrogen, ammonia, argon, neon, helium, or combinations thereof. In one example, the carrier gas contains nitrogen.

Thereafter, the flow of the reagent gas may be maintained or adjusted before igniting a plasma. The substrate may be exposed to the plasma for a time period within a range from about 0.1 seconds to about 20 seconds, preferably, from about 1 second to about 10 seconds, and more preferably, from about 2 seconds to about 8 seconds. Thereafter, the plasma power is turned off. In one example, the reagent may be ammonia, nitrogen, hydrogen, or combinations thereof to form an ammonia plasma, a nitrogen plasma, a hydrogen plasma, or a combined plasma. The reactant plasma reacts with the adsorbed titanium precursor on the substrate to form a titanium material thereon. In one example, the reactant plasma is used as a reducing agent (e.g., H₂) to form metallic titanium. However, a variety of reactants may be used to form titanium materials having a wide range of compositions. In one example, a boron-containing reactant compound (e.g., diborane) is used to form a titanium material containing boride. In another example, a silicon-containing reactant compound (e.g., silane) is used to form a titanium material containing silicide.

In another example, a nitrogen plasma or a nitrogen precursor (e.g., nitrogen or ammonia) may be used to form a titanium material containing nitrogen, such as titanium nitride or titanium aluminum nitride. In another example, an aluminum precursor and the nitrogen precursor may be is used to form a titanium aluminum nitride material. The nitrogen precursor may be a gas or a plasma and may contain nitrogen, ammonia, hydrogen, or mixtures thereof. In many examples, a nitrogen plasma formed from igniting a gas containing ammonia may be exposed to absorbed layers of titanium precursor, titanium nitride layers, aluminum layers, layers of titanium aluminum nitride material, as well as exposed to the substrate or substrate surface during vapor deposition processes, ALD or PE-ALD processes, CVD or PE-CVD processes, pretreatment, treatment, and/or post-treatment processes.

The processing chamber was exposed to a second purge step to remove excess precursors or contaminants from the previous step. The flow rate of the reagent gas may be maintained or adjusted from the previous step during the purge step. An optional purge gas may be administered into the processing chamber with a flow rate within a range from about 100 sccm to about 2,000 sccm, preferably, from about 200 sccm to about 1,000 sccm, and more preferably, from about 300 sccm to about 700 sccm, for example, about 500 sccm. The second purge step may be conducted for a time period within a range from about 0.1 seconds to about 8 seconds, preferably, from about 1 second to about 5 seconds, and more preferably, from about 2 seconds to about 4 seconds.

In one embodiment, the ALD cycle may be repeated until a predetermined thickness of the titanium nitride is deposited on the substrate. In another embodiment, the titanium nitride layer is exposed to an aluminum precursor gas, subsequently, the ALD cycle and/or the exposure of the aluminum precursor gas may be repeated until a predetermined thickness of the titanium aluminum nitride is deposited on the substrate.

The titanium material may be deposited with a thickness less than 1,000 Å, preferably less than 500 Å, and more preferably from about 10 Å to about 100 Å, for example, about 30 Å. The processes as described herein may deposit a titanium material at a rate of at least 0.15 Å/cycle, preferably, at least 0.25 Å/cycle, more preferably, at least 0.35 Å/cycle or faster. In another embodiment, the processes as described herein overcome shortcomings of the prior art relative as related to nucleation delay. There is no detectable nucleation delay during many, if not most, of the experiments to deposit the titanium materials.

As used herein, “TiAlN” is used as an abbreviation for titanium aluminum nitride, a titanium aluminum nitride material, or a titanium aluminum nitride layer, but does not imply a particular stoichiometry of titanium aluminum nitride, unless otherwise described or noted by a specific chemical formula. In other embodiments, the titanium aluminum nitride (TiAlN) material contains an aluminum concentration within a range from about 2 atomic percent to about 40 atomic percent, preferably, from about 5 atomic percent to about 33 atomic percent. The titanium aluminum nitride material may contain a carbon concentration of about 5 atomic percent or less, preferably, about 3 atomic percent or less, and more preferably, about 2 atomic percent or less, and more preferably, about 1 atomic percent or less, and more preferably, about 0.5 atomic percent or less. In other embodiments, the titanium aluminum nitride material may contain a carbon concentration of about 15 atomic percent or less, such as about 10 atomic percent or less, such as about 5 atomic percent. Generally, prior to being exposed to the aluminum precursor gas, the titanium nitride layer may have a thickness within a range from about 2 Å to about 300 Å, preferably, from about 5 Å to about 200 Å. The aluminum layer may have a thickness within a range from about 2 Å to about 20 Å, preferably, from about 2 Å to about 10 Å. In some embodiments, the concentrations of titanium, nitrogen, and/or aluminum may have a gradient throughout the titanium aluminum nitride material. In one example, multiple layers of titanium nitride are deposited on the substrate before exposing the titanium nitride layer to the aluminum precursor gas and depositing an aluminum layer thereon. In another example, multiple layers of aluminum are deposited on the substrate before depositing a titanium nitride layer thereon. In another example, multiple layers of a titanium aluminum material are deposited on the substrate before exposing the substrate to a nitrogen plasma or other nitridation process.

In another embodiment, the titanium aluminum nitride material may be a metal gate layer on the substrate. The metal gate layer containing the titanium aluminum nitride material may have a thickness within a range from about 10 Å to about 100 Å, preferably, from about 20 Å to about 80 Å, or from about 30 Å to about 40 Å. In another embodiment, the titanium aluminum nitride material may be a layer within a capacitor. The capacitor layer containing the titanium aluminum nitride material may have a thickness within a range from about 50 Å to about 500 Å, preferably, from about 100 Å to about 200 Å, for example, about 150 Å.

In another embodiment, the titanium aluminum nitride material may be a barrier layer on the substrate. The barrier layer containing the titanium aluminum nitride material may have a thickness within a range from about 5 Å to about 50 Å, preferably, from about 15 Å to about 30 Å, for example, about 20 Å. In one embodiment, a metal-containing layer, such as a seed layer or a bulk layer, is disposed on or over the barrier layer containing the titanium aluminum nitride material. The metal-containing layer may contain copper, cobalt, ruthenium, tungsten, palladium, aluminum, alloys thereof, or combinations thereof.

In another embodiment, a titanium material may be formed during another PE-ALD process that provides sequentially exposing the substrate to pulses of a titanium precursor and an active reagent, such as a reagent plasma. The substrate may be exposed to a titanium precursor gas formed by passing a carrier gas through an ampoule containing a titanium precursor, as described herein. The titanium precursor gas usually has a flow rate within a range from about 100 sccm to about 2,000 sccm, preferably, from about 200 sccm to about 1,000 sccm, and more preferably, from about 300 sccm to about 700 sccm, for example, about 500 sccm. The substrate may be exposed to the deposition gas containing the titanium precursor and the reagent gas for a time period within a range from about 0.1 seconds to about 8 seconds, preferably, from about 1 second to about 5 seconds, and more preferably from about 2 seconds to about 4 seconds. The flow of the titanium precursor gas may be stopped once the titanium precursor is adsorbed on the substrate. The titanium precursor may be a discontinuous layer, continuous layer or even multiple layers.

Subsequently, the substrate and chamber are exposed to a purge step. A purge gas may be administered into the processing chamber during the purge step. In one aspect, the purge gas is the reagent gas, such as ammonia, nitrogen or hydrogen. In another aspect, the purge gas may be a different gas than the reagent gas. For example, the reagent gas may be ammonia and the purge gas may be nitrogen, hydrogen or argon. The purge gas may have a flow rate within a range from about 100 sccm to about 2,000 sccm, preferably, from about 200 sccm to about 1,000 sccm, and more preferably, from about 300 sccm to about 700 sccm, for example, about 500 sccm. The purge step removes any excess titanium precursor and other contaminants within the processing chamber. The purge step may be conducted for a time period within a range from about 0.1 seconds to about 8 seconds, preferably, from about 1 second to about 5 seconds, and more preferably, from about 2 seconds to about 4 seconds. A carrier gas, a purge gas, a deposition gas, or other process gas may contain nitrogen, hydrogen, ammonia, argon, neon, helium or combinations thereof.

The substrate and the adsorbed titanium precursor thereon may be exposed to the reagent gas during the next step of the ALD process. Optionally, a carrier gas may be administered at the same time as the reagent gas into the processing chamber. The reagent gas may be ignited to form a plasma. The reagent gas usually has a flow rate within a range from about 100 sccm to about 3,000 sccm, preferably, from about 200 sccm to about 2,000 sccm, and more preferably, from about 500 sccm to about 1,500 sccm. In one example, ammonia is used as a reagent gas with a flow rate of about 1,500 sccm. The substrate may be exposed to the plasma for a time period within a range from about 0.1 seconds to about 20 seconds, preferably, from about 1 second to about 10 seconds, and more preferably, from about 2 seconds to about 8 seconds. Thereafter, the plasma power may be turned off. In one example, the reagent may be ammonia, nitrogen, hydrogen or combinations thereof, while the plasma may be an ammonia plasma, a nitrogen plasma, a hydrogen plasma or a combination thereof. The reactant plasma reacts with the adsorbed titanium precursor on the substrate to form a titanium material thereon. Preferably, the reactant plasma is used as a reducing agent to form metallic titanium. However, a variety of reactants may be used to form titanium materials having a wide range of compositions, as described herein.

The processing chamber may be exposed to a second purge step to remove excess precursors or contaminants from the processing chamber. The flow of the reagent gas may have been stopped at the end of the previous step and started during the purge step, if the reagent gas is used as a purge gas. Alternatively, a purge gas that is different than the reagent gas may be administered into the processing chamber. The reagent gas or purge gas may have a flow rate within a range from about 100 sccm to about 2,000 sccm, preferably, from about 200 sccm to about 1,000 sccm, and more preferably, from about 300 sccm to about 700 sccm, for example, about 500 sccm. The second purge step may be conducted for a time period within a range from about 0.1 seconds to about 8 seconds, preferably, from about 1 second to about 5 seconds, and more preferably, from about 2 seconds to about 4 seconds.

The ALD cycle may be repeated until a predetermined thickness of the titanium material is deposited on the substrate. The titanium material may be deposited with a thickness less than 1,000 Å, preferably less than 500 Å and more preferably from about 10 Å to about 100 Å, for example, about 30 Å. The processes as described herein may deposit a titanium material at a rate of at least 0.15 Å/cycle, preferably, at least 0.25 Å/cycle, more preferably, at least 0.35 Å/cycle or faster. In another embodiment, the processes as described herein overcome shortcomings of the prior art relative as related to nucleation delay.

The titanium precursor and at least one reagent may be sequentially introduced into the processing chamber and the substrate exposed during a vapor deposition process, such as a thermal ALD process or a PE-ALD process. The titanium materials formed by processes herein include metallic titanium, titanium nitride, titanium silicon nitride, titanium aluminum nitride, titanium aluminum alloy, or derivatives thereof. A suitable reagent for forming a titanium material may be a nitrogen precursor or a reducing gas and include nitrogen (e.g., N₂ or atomic-N), hydrogen (e.g., H₂ or atomic-H), ammonia (NH₃), hydrazine (N₂H₄), silane (SiH₄), disilane (Si₂H₆), trisilane (Si₃H₈), tetrasilane (Si₄H₁₀), dimethylsilane (SiC₂H₈), methyl silane (SiCH₆), ethylsilane (SiC₂H₈), chlorosilane (ClSiH₃), dichlorosilane (Cl₂SiH₂), hexachlorodisilane (Si₂Cl₆), borane (BH₃), diborane (B₂H₆), triethylborane (Et₃B), derivatives thereof, plasmas thereof, or combinations thereof. In other embodiments, an aluminum precursor such as tris(tertbutyl) aluminum (((CH₃)₃C)₃Al or ^{t}Bu₃Al or TTBA) or derivatives thereof may be used as the reagent while forming titanium aluminum nitride materials during vapor deposition processes described herein.

The time interval for the pulse of the titanium precursor is variable depending upon a number of factors such as, for example, the volume capacity of the processing chamber employed, the vacuum system coupled thereto and the volatility/reactivity of the reactants used during the ALD process. For example, (1) a large-volume processing chamber may lead to a longer time to stabilize the process conditions such as, for example, carrier/purge gas flow and temperature, requiring a longer pulse time; (2) a lower flow rate for the deposition gas may also lead to a longer time to stabilize the process conditions requiring a longer pulse time; and (3) a lower chamber pressure means that the deposition gas is evacuated from the processing chamber more quickly requiring a longer pulse time. In general, the process conditions are advantageously selected so that a pulse of the titanium precursor provides a sufficient amount of precursor so that at least a monolayer of the titanium precursor is adsorbed on the substrate. Thereafter, excess titanium precursor remaining in the chamber may be removed from the processing chamber by the constant carrier gas stream in combination with the vacuum system.

The time interval for each of the pulses of the titanium precursor and the reagent gas may have the same duration. That is, the duration of the pulse of the titanium precursor may be identical to the duration of the pulse of the reagent gas. For such an embodiment, a time interval (T₁) for the pulse of the titanium precursor (e.g., TDMAT) is equal to a time interval (T₂) for the pulse of the reagent gas (e.g., nitrogen plasma).

Alternatively, the time interval for each of the pulses of the titanium precursor and the reagent gas may have different durations. That is, the duration of the pulse of the titanium precursor may be shorter or longer than the duration of the pulse of the reagent gas. For such an embodiment, a time interval (T₁) for the pulse of the titanium precursor is different than the time interval (T₂) for the pulse of the reagent gas.

In addition, the periods of non-pulsing between each of the pulses of the titanium precursor and the reagent gas may have the same duration. That is, the duration of the period of non-pulsing between each pulse of the titanium precursor and each pulse of the reagent gas is identical. For such an embodiment, a time interval (T₃) of non-pulsing between the pulse of the titanium precursor and the pulse of the reagent gas is equal to a time interval (T₄) of non-pulsing between the pulse of the reagent gas and the pulse of the titanium precursor. During the time periods of non-pulsing only the constant carrier gas stream is provided to the processing chamber.

Alternatively, the periods of non-pulsing between each of the pulses of the titanium precursor and the reagent gas may have different duration. That is, the duration of the period of non-pulsing between each pulse of the titanium precursor and each pulse of the reagent gas may be shorter or longer than the duration of the period of non-pulsing between each pulse of the reagent gas and the titanium precursor. For such an embodiment, a time interval (T₃) of non-pulsing between the pulse of the titanium precursor and the pulse of the reagent gas is different from a time interval (T₄) of non-pulsing between the pulse of the reagent gas and the pulse of titanium precursor. During the time periods of non-pulsing only the constant carrier gas stream is provided to the processing chamber.

Additionally, the time intervals for each pulse of the titanium precursor, the reagent gas and the periods of non-pulsing therebetween for each deposition cycle may have the same duration. For such an embodiment, a time interval (T₁) for the titanium precursor, a time interval (T₂) for the reagent gas, a time interval (T₃) of non-pulsing between the pulse of the titanium precursor and the pulse of the reagent gas and a time interval (T₄) of non-pulsing between the pulse of the reagent gas and the pulse of the titanium precursor each have the same value for each deposition cycle. For example, in a first deposition cycle (C₁), a time interval (T₁) for the pulse of the titanium precursor has the same duration as the time interval (T₁) for the pulse of the titanium precursor in subsequent deposition cycles (C₂ . . . Cₙ). Similarly, the duration of each pulse of the reagent gas and the periods of non-pulsing between the pulse of the titanium precursor and the reagent gas in the first deposition cycle (C₁) is the same as the duration of each pulse of the reagent gas and the periods of non-pulsing between the pulse of the titanium precursor and the reagent gas in subsequent deposition cycles (C₂ . . . Cₙ), respectively.

Alternatively, the time intervals for at least one pulse of the titanium precursor, the reagent gas and the periods of non-pulsing therebetween for one or more of the deposition cycles of the titanium material deposition process may have different durations. For such an embodiment, one or more of the time intervals (T₁) for the pulses of the titanium precursor, the time intervals (T₂) for the pulses of the reagent gas, the time intervals (T₃) of non-pulsing between the pulse of the titanium precursor and the reagent gas and the time intervals (T₄) of non-pulsing between the pulses of the reagent gas and the titanium precursor may have different values for one or more deposition cycles of the cyclical deposition process. For example, in a first deposition cycle (C₁), the time interval (T₁) for the pulse of the titanium precursor may be longer or shorter than one or more time interval (T₁) for the pulse of the titanium precursor in subsequent deposition cycles (C₂ . . . Cₙ). Similarly, the durations of the pulses of the reagent gas and the periods of non-pulsing between the pulse of the titanium precursor and the reagent gas in the first deposition cycle (C₁) may be the same or different than the duration of each pulse of the reagent gas and the periods of non-pulsing between the pulse of the titanium precursor and the reagent gas in subsequent deposition cycles (C₂ . . . Cₙ).

In some embodiments, a constant flow of a carrier gas or a purge gas may be provided to the processing chamber modulated by alternating periods of pulsing and non-pulsing where the periods of pulsing alternate between the titanium precursor and the reagent gas along with the carrier/purge gas stream, while the periods of non-pulsing include only the carrier/purge gas stream.

In one example, a copper seed layer may be formed on the titanium aluminum nitride material by a CVD process and thereafter, copper bulk is deposited to fill the interconnect by an ECP process. In another example, a copper seed layer may be formed on the titanium aluminum nitride material by a PVD process and thereafter, copper bulk is deposited to fill the interconnect by an ECP process. In another example, a copper seed layer may be formed on the titanium aluminum nitride material by an electroless process and thereafter, copper bulk is deposited to fill the interconnect by an ECP process. In another example, the titanium aluminum nitride material serves as a seed layer to which a copper bulk fill is directly deposited by an ECP process or an electroless deposition process.

In another example, a tungsten seed layer may be formed on the titanium aluminum nitride material by a PE-ALD process and thereafter, bulk tungsten is deposited to fill the interconnect by a CVD process or a pulsed-CVD process. In another example, a tungsten seed layer may be formed on the titanium aluminum nitride material by a PVD process and thereafter, bulk tungsten is deposited to fill the interconnect by a CVD process or a pulsed-CVD process. In another example, a tungsten seed layer may be formed on the titanium aluminum nitride material by a PE-ALD process and thereafter, bulk tungsten is deposited to fill the interconnect by an ECP process. In another example, the titanium aluminum nitride material serves as a seed layer to which a tungsten bulk fill is directly deposited by a CVD process or a pulsed-CVD process.

In another example, a seed layer containing cobalt or ruthenium may be formed on the titanium aluminum nitride material by a PE-ALD process and thereafter, bulk tungsten or copper is deposited to fill the interconnect by a CVD process or a pulsed-CVD process. In another example, a seed layer containing cobalt or ruthenium may be formed on the titanium aluminum nitride material by a PVD process and thereafter, bulk tungsten or copper is deposited to fill the interconnect by a CVD process or a pulsed-CVD process. In another example, a seed layer containing cobalt or ruthenium may be formed on the titanium aluminum nitride material by a PE-ALD process and thereafter, bulk tungsten or copper is deposited to fill the interconnect by an ECP process.

In another embodiment, capacitor electrodes, such as utilized in dynamic random access memory (DRAM), contain the titanium aluminum nitride material formed by the processes described herein. In one example, the bottom electrode contains titanium aluminum nitride deposited on the bottom surface of a trench formed within an oxide material, such as silicon oxide. The bottom electrode containing the titanium aluminum nitride material may have a thickness within a range from about 25 Å to about 500 Å, preferably, from about 50 Å to about 200 Å, for example, about 100 Å or about 150 Å. The bottom surface may be a contact layer containing polysilicon or a metal, such as tungsten, copper, aluminum, silver, alloys thereof, or derivatives thereof. The DRAM capacitor may further contain a high-k oxide layer disposed over the bottom electrode, and a top electrode disposed over the high-k oxide layer. The high-k oxide layer may contain a high-k oxide, such as zirconium oxide, strontium titanium oxide, barium strontium titanate, or derivatives thereof.

Several integration sequences may be conducted before and/or subsequent formation a titanium aluminum nitride material/layer within an interconnect containing copper or copper alloy in some embodiments provided herein. In one example, the subsequent steps follow: a) pre-clean of the substrate; b) deposition of a barrier layer containing titanium aluminum nitride by PE-ALD; c) deposition of copper seed by electroless, ECP, or PVD; and d) deposition of copper bulk by ECP. In another example, the subsequent steps follow: a) deposition of a barrier layer (e.g., PE-ALD of TiAlN); b) punch through step; c) deposition of titanium aluminum nitride by PE-ALD; d) deposition of copper seed by electroless, ECP, or PVD; and e) deposition of copper bulk by ECP. In another example, the subsequent steps follow: a) deposition of titanium aluminum nitride by PE-ALD; b) punch through step; c) deposition of titanium aluminum nitride by PE-ALD; d) deposition of copper seed by electroless, ECP, or PVD; and e) deposition of copper bulk by electroless, ECP, or PVD. In another example, the subsequent steps follow: a) deposition of titanium aluminum nitride by PE-ALD; b) punch through step; c) deposition of titanium aluminum nitride by PE-ALD; and d) deposition of copper by electroless or ECP. In another embodiment, the subsequent steps follow: a) pre-clean of the substrate; b) deposition of titanium aluminum nitride by PE-ALD; c) deposition of copper seed by electroless, ECP, or PVD; and d) deposition of copper bulk by ECP. In another example, the subsequent steps follow: a) deposition of a barrier layer (e.g., PE-ALD of TiAlN); b) deposition of titanium aluminum nitride by PE-ALD; c) punch through step; d) deposition of titanium aluminum nitride by PE-ALD; e) deposition of copper seed by electroless, ECP, or PVD; and f) deposition of copper bulk by ECP. In another example, the subsequent steps follow: a) deposition of a barrier layer (e.g., PE-ALD of TiAlN); b) punch through step; c) deposition of a barrier layer (e.g., PE-ALD of TiAlN); d) deposition of titanium aluminum nitride by PE-ALD; and e) deposition of copper seed by electroless, ECP, or PVD; and f) deposition of copper bulk by ECP. In one example, the subsequent steps follow: a) pre-clean of the substrate; b) deposition of a barrier layer (e.g., PE-ALD of TiAlN); c) deposition of titanium aluminum nitride by PE-ALD; and d) deposition of copper bulk by electroless or ECP.

In other embodiments, several other integration sequences may be conducted before and/or subsequent formation a titanium aluminum nitride material/layer within an interconnect containing tungsten, tungsten alloy, copper, or copper alloy. In one example, the subsequent steps follow: a) pre-clean of the substrate; b) deposition of a barrier layer containing titanium aluminum nitride by PE-ALD; c) deposition of seed layer containing cobalt or ruthenium by electroless, ECP, or PVD; and d) deposition of bulk layer containing copper or tungsten by ECP. In another example, the subsequent steps follow: a) deposition of a barrier layer (e.g., PE-ALD of TiAlN); b) punch through step; c) deposition of titanium aluminum nitride by PE-ALD; d) deposition of seed layer containing cobalt or ruthenium by electroless, ECP, or PVD; and e) deposition of bulk layer containing copper or tungsten by ECP. In another example, the subsequent steps follow: a) deposition of titanium aluminum nitride by PE-ALD; b) punch through step; c) deposition of titanium aluminum nitride by PE-ALD; d) deposition of seed layer containing cobalt or ruthenium by electroless, ECP, or PVD; and e) deposition of bulk layer containing copper or tungsten by electroless, ECP, or PVD. In another example, the subsequent steps follow: a) deposition of titanium aluminum nitride by PE-ALD; b) punch through step; c) deposition of titanium aluminum nitride by PE-ALD; and d) deposition of copper by electroless or ECP. In another embodiment, the subsequent steps follow: a) pre-clean of the substrate; b) deposition of titanium aluminum nitride by PE-ALD; c) deposition of seed layer containing cobalt or ruthenium by electroless, ECP, or PVD; and d) deposition of bulk layer containing copper or tungsten by ECP. In another example, the subsequent steps follow: a) deposition of a barrier layer (e.g., PE-ALD of TiAlN); b) deposition of titanium aluminum nitride by PE-ALD; c) punch through step; d) deposition of titanium aluminum nitride by PE-ALD; e) deposition of seed layer containing cobalt or ruthenium by electroless, ECP, or PVD; and f) deposition of bulk layer containing copper or tungsten by ECP. In another example, the subsequent steps follow: a) deposition of a barrier layer (e.g., PE-ALD of TiAlN); b) punch through step; c) deposition of a barrier layer (e.g., PE-ALD of TiAlN); d) deposition of titanium aluminum nitride by PE-ALD; and e) deposition of seed layer containing cobalt or ruthenium by electroless, ECP, or PVD; and f) deposition of bulk layer containing copper or tungsten by ECP. In one example, the subsequent steps follow: a) pre-clean of the substrate; b) deposition of a barrier layer (e.g., PE-ALD of TiAlN); c) deposition of titanium aluminum nitride by PE-ALD; and d) deposition of bulk layer containing copper or tungsten by electroless or ECP.

The pre-clean steps include methods to clean or purify the via, such as the removal of residue at the bottom of the via (e.g., carbon) or reduction of copper oxide to copper metal. Punch through steps include a method to remove material (e.g., barrier layer) from the bottom of the via to expose conductive layer, such as copper. Further disclosure of punch through steps is described in more detail in the commonly assigned, U.S. Pat. No. 6,498,091, which is incorporated herein in its entirety by reference. The punch through steps may be conducted within a processing chamber, such as either a barrier chamber or a clean chamber. In embodiments of the invention, clean steps and punch through steps are applied to titanium aluminum nitride barrier layers. Further disclosure of overall integrated methods are described in more detail in the commonly assigned, U.S. Pat. No. 7,049,226, which is incorporated herein in its entirety by reference. In some embodiments, the titanium aluminum nitride materials formed during the PE-ALD processes as described herein may have a sheet resistance of less than 2,000 μΩ-cm, preferably, less than 1,000 μΩ-cm, and more preferably, less than 500 μΩ-cm.

In another embodiment, the titanium aluminum nitride materials described herein may be used to form memory device electrodes, such as phase-change memory (PCM) electrodes or phase-change random access memory (PRAM) electrodes. The PRAM capacitor utilizes the unique behavior of a chalcogenide material or glass which can be changed or switched between a crystalline state and an amorphous state by the application of heat. The PRAM capacitor may contain a bottom electrode containing a titanium aluminum nitride material and disposed over a contact surface, a high resistance layer (resistor) containing a titanium aluminum nitride material disposed over the bottom electrode, a phase-change material layer disposed over the resistance layer or resistor, and a top electrode that may contain a titanium aluminum nitride material disposed over the phase-change material. The phase-change material layer may be a chalcogenide alloy or chalcogenide glass and contain germanium, antimony, tellurium, selenium, indium, silver, alloys thereof, derivatives thereof, or combinations thereof. Some exemplary alloys that the phase-change material layer may contain include germanium antimony tellurium alloy, germanium antimony tellurium selenium alloy, silver indium antimony tellurium alloy, silver indium antimony selenium tellurium alloy, indium selenium alloy, antimony selenium alloy, antimony tellurium alloy, indium antimony selenium alloy, indium antimony tellurium alloy, germanium antimony selenium alloy, alloys thereof, derivatives thereof, or combinations thereof. The contact surface may be the surface of a material containing a layer or multiple layers of metals and/or other conductive materials which include titanium, tungsten, copper, cobalt, ruthenium, nickel, platinum, aluminum, silver, polysilicon, doped polysilicon, derivatives thereof, alloys thereof, or combinations thereof.

In another embodiment, at least one layer containing the titanium aluminum nitride materials described herein may be included within a dynamic random access memory (DRAM) buried word line (bWL) or buried bit line (bBL). In some examples, a liner layer containing titanium aluminum nitride material may be contained within a DRAM bWL or a DRAM bBL. The liner layer may be disposed on or over an oxide film and/or a contact surface, and a low-resistance material may be disposed on or over the liner film to act as a fill material. In some examples, the low-resistance material may be absent and the liner layer containing the titanium aluminum nitride material may be contained within the fill material/layer. The contact surface may be the surface of a material containing a layer or multiple layers of metals and/or other conductive materials which include titanium, tungsten, copper, cobalt, ruthenium, nickel, platinum, aluminum, silver, polysilicon, doped polysilicon, derivatives thereof, alloys thereof, or combinations thereof.

In another embodiment, a logic or peripheral DRAM metal gate may contain the titanium aluminum nitride materials described herein. The metal gate integration scheme may follow a gate first scheme or a gate last scheme. The first gate scheme may contain a work function material/layer containing titanium aluminum nitride material disposed on or over a high-k oxide layer and a hardmask layer disposed on or over the work function layer. The high-k oxide layer contains at least one high-k material such as hafnium oxide, hafnium silicate, hafnium aluminum silicate, zirconium oxide, strontium titanium oxide, barium strontium titanate, derivatives thereof, silicates thereof, aluminates thereof, or combinations thereof. The high-k oxide layer may contain a single layer of high-k material, or may contain multiple layers of high-k materials, such as a high-k stack. The hardmask layer may contain polysilicon, titanium nitride, or derivatives thereof. In the gate last scheme, a work function material/layer and/or a barrier layer may independently contain the titanium aluminum nitride materials described herein. When used as a work function material, titanium aluminum nitride may be disposed over a hard mask material (e.g., titanium nitride) or directly over a high-k material (e.g., hafnium oxide or derivatives thereof). A wetting layer such as metallic titanium, titanium alloy, or derivatives thereof for low-resistance fill may be disposed over the work function material. A barrier layer containing the titanium aluminum nitride material may be disposed over a work function material/layer such as titanium nitride, cobalt, nickel, ruthenium, or derivatives thereof. A wetting layer such as titanium or derivatives thereof for low-resistance fill may be disposed over the barrier layer.

A “substrate surface,” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride. Substrates may have various dimensions, such as 200 mm or 300 mm diameter wafers, as well as, rectangular or square panes. Unless otherwise noted, embodiments and examples described herein are preferably conducted on substrates with a 200 mm diameter or a 300 mm diameter, more preferably, a 300 mm diameter. Processes of the embodiments described herein deposit titanium nitride, titanium aluminum nitride, other titanium materials (e.g., metallic titanium or titanium silicon nitride) and aluminum nitride materials on many substrates and surfaces. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers and patterned or non-patterned wafers. Substrates may be exposed to a pretreatment process to polish, etch, reduce, oxidize, hydroxylate, anneal and/or bake the substrate surface.

“Atomic layer deposition” (ALD) or “cyclical deposition” as used herein refers to the sequential introduction of two or more reactive compounds to deposit a layer of material on a substrate surface. The two, three or more reactive compounds may alternatively be introduced into a reaction zone or process region of a processing chamber. The reactive compounds may be in a state of gas, plasma, vapor, fluid or other state of matter useful for a vapor deposition process. Usually, each reactive compound is separated by a time delay to allow each compound to adhere and/or react on the substrate surface. In one aspect, a first precursor or compound A is pulsed into the reaction zone followed by a first time delay. Next, a second precursor or compound B is pulsed into the reaction zone followed by a second delay. Compound A and compound B react to form a deposited material. During each time delay, a purge gas is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film thickness of the deposited material is formed on the substrate surface. In either scenario, the ALD process of pulsing compound A, purge gas, pulsing compound B and purge gas is a cycle. A cycle can start with either compound A or compound B and continue the respective order of the cycle until achieving a film with the desired thickness. In another embodiment, a first precursor containing compound A, a second precursor containing compound B and a third precursor containing compound C are each separately pulsed into the processing chamber. Alternatively, a pulse of a first precursor may overlap in time with a pulse of a second precursor while a pulse of a third precursor does not overlap in time with either pulse of the first and second precursors. A deposition gas or a process gas as used herein refers to a single gas, multiple gases, a gas containing a plasma, combinations of gas(es) and/or plasma(s). A deposition gas may contain at least one reactive compound for a vapor deposition process. The reactive compounds may be in a state of gas, plasma, vapor, fluid during the vapor deposition process. Also, a process may contain a purge gas or a carrier gas and not contain a reactive compound.

While foregoing is directed to the preferred embodiment of the invention, other and further embodiments of the invention may be devised without departing from the basic scope thereof, and the scope thereof is determined by the claims that follow.

1. A method for forming a titanium aluminum nitride material on a substrate surface, comprising:
exposing a substrate sequentially to a titanium precursor gas and a nitrogen plasma to form a titanium nitride layer on the substrate during a plasma enhanced atomic layer deposition process;
exposing the titanium nitride layer to a plasma during a treatment process;
exposing the titanium nitride layer to an aluminum precursor gas while depositing an aluminum layer thereon during a vapor deposition process; and
repeating sequentially the plasma enhanced atomic layer deposition process, the treatment process, and the vapor deposition process to form the titanium aluminum nitride material from the titanium nitride layer and the aluminum layer.

2. The method of claim 1, wherein the titanium precursor gas comprises a titanium precursor selected from the group consisting of tetrakis(dimethylamino) titanium, tetrakis(diethylamino) titanium, tetrakis(methylethylamino) titanium, and derivatives thereof.

3. The method of claim 2, wherein the titanium precursor is tetrakis(dimethylamino) titanium.

4. The method of claim 1, wherein the aluminum precursor gas comprises an aluminum precursor selected from the group consisting of tris(tertbutyl) aluminum, trimethyl aluminum, aluminum chloride, and derivatives thereof.

5. The method of claim 4, wherein the aluminum precursor is tris(tertbutyl) aluminum.

6. The method of claim 1, wherein the nitrogen plasma is formed from a gas selected from the group consisting of nitrogen, ammonia, hydrogen, derivatives thereof, and mixtures thereof.

7. The method of claim 6, wherein the nitrogen plasma comprises nitrogen (N₂) or ammonia.

8. The method of claim 1, wherein the plasma exposed to the titanium nitride layer during the treatment process comprises a gas selected from the group consisting of nitrogen, ammonia, hydrogen, argon, derivatives thereof, and mixtures thereof.

9. The method of claim 8, wherein the plasma exposed to the titanium nitride layer during the treatment process comprises nitrogen (N₂) or ammonia.

10. The method of claim 1, wherein the titanium precursor is tetrakis(dimethylamino) titanium, the aluminum precursor is tris(tertbutyl) aluminum, and the nitrogen precursor is a nitrogen plasma.

11. The method of claim 1, wherein the titanium nitride layer has a thickness within a range from about 5 Å to about 200 Å.

12. The method of claim 1, wherein the titanium aluminum nitride material has an aluminum concentration within a range from about 5 atomic percent to about 33 atomic percent.

13. The method of claim 1, wherein the titanium aluminum nitride material comprises a carbon concentration of about 15 atomic percent or less.

14. The method of claim 1, wherein the titanium aluminum nitride material is a metal gate layer on the substrate.

15. The method of claim 14, wherein the metal gate layer has a thickness within a range from about 20 Å to about 80 Å.

16. The method of claim 1, wherein the titanium aluminum nitride material is a barrier layer on the substrate and the barrier layer has a thickness within a range from about 15 Å to about 30 Å.

17. The method of claim 16, wherein a metal-containing layer is disposed over the barrier layer, and the metal-containing layer comprises copper, cobalt, or ruthenium.

18. The method of claim 1, wherein the titanium aluminum nitride material is an electrode layer within a capacitor on the substrate, and the electrode layer of the titanium aluminum nitride material has a thickness within a range from about 50 Å to about 200 Å.

19. A method for forming a titanium aluminum nitride material on a substrate surface, comprising:
exposing a substrate sequentially to a titanium precursor gas and a nitrogen precursor while forming a first titanium nitride layer thereon;
exposing the first titanium nitride layer to a plasma during a treatment process;
exposing the first titanium nitride layer to an aluminum precursor gas while depositing a first aluminum layer thereon;
exposing the substrate sequentially to the titanium precursor gas and the nitrogen precursor while forming a second titanium nitride layer on the first aluminum layer;
exposing the second titanium nitride layer to the plasma during the treatment process; and
exposing the second titanium nitride layer to the aluminum precursor gas while depositing a second aluminum layer thereon.

20. A method for forming a titanium aluminum nitride material on a substrate surface, comprising:
exposing a substrate sequentially to a titanium precursor gas and a nitrogen precursor while forming a first titanium nitride layer thereon;
exposing the first titanium nitride layer to a first plasma during a first treatment process;
exposing the first titanium nitride layer to an aluminum precursor gas while depositing a first aluminum layer thereon;
exposing the first aluminum layer to a second plasma during a second treatment process;
exposing the substrate sequentially to the titanium precursor gas and the nitrogen precursor while forming a second titanium nitride layer on the first aluminum layer;
exposing the second titanium nitride layer to the first plasma during the first treatment process;
exposing the second titanium nitride layer to the aluminum precursor gas while depositing a second aluminum layer thereon; and
exposing the second aluminum layer to the second plasma during the second treatment process.

21. A method for forming a titanium aluminum nitride material on a substrate surface, comprising:
exposing a substrate to a deposition gas comprising a titanium precursor and an aluminum precursor while forming an absorbed layer thereon;
exposing the absorbed layer to a nitrogen plasma while forming a titanium aluminum nitride layer on the substrate; and
repeating sequential exposures of the deposition gas and the nitrogen plasma to form a plurality of titanium aluminum nitride layers on the substrate.

22. A dynamic random access memory (DRAM) capacitor, comprising:
a bottom electrode comprising titanium aluminum nitride and disposed over a contact surface;
a high-k oxide layer disposed over the bottom electrode; and
a top electrode comprising titanium aluminum nitride and disposed over the high-k oxide layer.

23. The DRAM capacitor of claim 22, wherein:
the contact surface comprises a material selected from the group consisting of titanium, tungsten, copper, cobalt, ruthenium, nickel, platinum, aluminum, silver, polysilicon, doped polysilicon, derivatives thereof, alloys thereof, and combinations thereof; and
the high-k oxide layer comprises a high-k material selected from the group consisting of hafnium oxide, hafnium silicate, hafnium aluminum silicate, zirconium oxide, strontium titanium oxide, barium strontium titanate, derivatives thereof, silicates thereof, aluminates thereof, and combinations thereof.

24. The DRAM capacitor of claim 22, wherein the bottom electrode, the high-k oxide layer, and the top electrode are within a trench formed in an oxide material disposed on a substrate.

25. The DRAM capacitor of claim 22, wherein the DRAM capacitor is a buried word line (bWL) DRAM or a buried bit line (bBL) DRAM.
